(19) United States
(12) Patent Application Publication
(10) Pub. No.: US 2023/0268460 A1
(43) Pub. Date: Aug. 24, 2023

(54) OPTOELECTRONIC DEVICE AND MANUFACTURING METHOD

(71) Applicant: ALEDIA, Echirolles (FR)

(72) Inventors: Benoit AMSTATT, Grenoble (FR); Pierre TCHOULFIAN, Grenoble (FR); Jerome NAPIERALA, Saint Egreve (FR)

(21) Appl. No.: 18/004,002

(22) PCT Filed: Jun. 29, 2021
(86) PCT No.: PCT/EP2021/067780

§ 371 Date: Dec. 30, 2022

(30) Foreign Application Priority Data
Jun. 30, 2020 (FR) 2006904

(51) Int. Cl. H01L 33/08; H01L 33/10; H01L 33/00; H01L 33/32

(52) U.S. Cl. CPC H01L 33/08; H01L 33/0075; H01L 33/105; H01L 33/32

(57) ABSTRACT

A method for manufacturing an optoelectronic device having a substrate and, on a first face of the substrate, at least one stack, in a longitudinal direction, of at least one injection layer of a first type of carriers and an active layer. The method including formation of a growth mask on the first face of the substrate, the growth mask having an opening in the longitudinal direction through which the first face is exposed, formation, from the exposed zone of the substrate, of the injection layer of the first type of carriers within the opening, formation of the active layer on the injection layer, within the opening, such that the active layer is confined in the opening and does not extend outside of the opening. One or more embodiment also relates to an optoelectronic device having an active layer confined in an opening of a growth mask.

### TECHNICAL FIELD

The invention relates to the field of optoelectronics. It has a particularly advantageous application in the field of gallium nitride (GaN)-based light-emitting diodes having a three-dimensional structure.

### STATE OF THE ART

Light-emitting diodes (LEDs) typically comprise a so-called active region, where radiative recombinations of electron-hole pairs occur, which make it possible to obtain a light radiation having a main wavelength.

For display applications, LEDs can be configured to produce a light radiation, the main wavelength of which is located in the blue, or in the green, or in the red. This main wavelength depends in particular on the configuration of the active region.

The active region or active layer of a GaN-based LED typically comprises InGaN-based quantum wells. These InGaN-based quantum wells can extend along different crystallographic planes, for example polar planes (c or -c planes of the hexagonal crystallographic structure), non-polar planes (a or m planes of the hexagonal crystallographic structure), or semi-polar.

The best internal quantum efficiency (IQE) is to date obtained when InGaN-based quantum wells extend along polar planes.

In the case of a GaN-based LED having a two-dimensional structure (2D LED), the formation of InGaN-based quantum wells along polar planes is facilitated.

However, in the case of a GaN-based LED having a three-dimensional structure (3D LED), for example in wire form, it is more difficult to form InGaN-based quantum wells along polar planes, in a so-called axial 3D LED architecture.

The manufacturing of axial 3D LEDs can be done by molecular beam epitaxy (MBE). This growth technique makes it possible to obtain, different from other growth techniques conventionally used, a localised deposition of InGaN at the top of the GaN-based wires. InGaN-based quantum wells can thus be formed along polar planes.

However, molecular beam epitaxy MBE does not have sufficient performance and is not a technique which is compatible with an industrial manufacturing method. Other growth techniques, typically metalorganic vapour-phase epitaxy (MOVPE), do not make it possible to make axial structures grow with good control. An interfering growth on the sides of the 3D structures is generally observed, leading to core-shell-type structures. These disadvantages limit the possibilities of manufacturing axial 3D LEDs industrially with good control.

The present invention aims to overcome at least partially the disadvantages mentioned above.

In particular, an aim of the present invention is to propose a method for manufacturing one or more optoelectronic devices, which is industrially compatible.

Another aim of the present invention is to propose an optoelectronic device, in particular a GaN-based axial 3D LED, which could be manufactured in an optimised manner.

Other aims, features and advantages of the present invention will appear upon examining the following description and accompanying drawings. It is understood that other advantages can be incorporated.

### SUMMARY

To achieve the aims mentioned above, an optoelectronic device comprising a substrate is provided, and on a first face of the substrate, at least one stack in a longitudinal direction, said stack comprising at least one injection layer of a first type of carriers and an active layer.

Advantageously, the optoelectronic device comprises a growth mask comprising a plurality of openings and the active layer of the at least one stack is confined in at least one opening of said openings and does not extend outside of said at least one opening. The growth mask typically makes it possible to guide at least partially a growth of the stack in the longitudinal direction. It is preferably configured to ensure this guiding function.

Thus, the active layer of the device has a pseudo-two-dimensional structure within the at least one opening. This pseudo-two-dimensional structure is linked to the presence of the growth mask over the whole height of the active layer. The device thus advantageously has a 3D architecture by benefiting from a pseudo-2D structure. The pseudo-2D structure of the active layer makes it possible to easily form in a compatible manner with an industrial manufacturing method, quantum wells along one single type of crystallographic planes, in particular along polar planes. This 3D architecture is called axial.

The integration of such a growth mask advantageously makes it possible to use the MOVPE to respectively form the injection layer and the active layer according to an axial 3D architecture. The growth mask can be made of a dielectric material so as to electrically insulate the substrate against a metal contact subsequently deposited on the top of the stacks, for example. It can also be transparent so as to let pass a light radiation emitted or received by the stacks.

According to a preferred, but optional embodiment, the stack(s) form(s) axial LEDs with a 3D structure within the growth mask. The device subsequently comprises at least one axial LED in the at least one opening of the growth mask. This axial LED is preferably grown by metalorganic vapour-phased epitaxy (MOVPE) directly within the at least one opening of the growth mask.

A second aspect relates to a method for manufacturing an optoelectronic device comprising a substrate and, on a first face of the substrate, at least one stack in a longitudinal direction of at least one injection layer of a first type of carriers and an active layer. This method comprises:
A provision of the substrate preferably comprising a nucleation layer,
A formation of a growth mask on the substrate, said growth mask comprising at least one opening in the longitudinal direction through which is exposed a zone of the substrate or of the nucleation layer,
A formation, from the exposed zone of the substrate or of the nucleation layer, of the injection layer of the first type of carriers within the at least one opening,
A formation of the active layer on said injection layer, within the at least one opening, such that said active layer is confined in the at least one opening and does not extend outside of said at least one opening.

According to a preferred, but optional embodiment, the formations of the injection layer and of the active layer are achieved by metalorganic vapour-phase epitaxy (MOVPE) in the longitudinal direction in the at least one opening.

The formation by metalorganic vapour-phase epitaxy MOVPE of the injection layer and/or of the active layer makes it possible to improve the industrial compatibility of the axial 3D LED manufacturing method.

According to a technical prejudice, it is generally accepted that MOVPE does not make it possible to form such axial 3D LEDs and that it is necessary to resort to MBE to manufacture such structures.

Thus, known solutions based on MBE in particular aim to size the equipment making it possible to implement MBE, such that they are compatible with an industrial production.

According to the technical prejudice mentioned above, metalorganic vapour-phase epitaxy MOVPE produces substantially conform layers. Thus, according to this prejudice, an MOVPE deposition of an injection layer and/or of an active layer on a protruding or recessed relief covers the side of said relief and the 3D structure obtained subsequently has a so-called radial architecture.

On the contrary, in the scope of the development of the present invention, it has surprisingly appeared that such an MOVPE deposition of an injection layer and/or an active layer within an opening of a growth mask makes it possible to obtain an axial 3D structure.

According to another aspect, the invention provides a growth mask for an optoelectronic device comprising a substrate and, on a first face of the substrate, at least one stack in a longitudinal direction, said stack comprising at least one injection layer of a first type of carriers and an active layer. The growth mask comprises a plurality of openings. The growth mask is configured to guide at least partially a growth of the stack in the longitudinal direction. The growth mask is shaped such that the active layer of the at least one stack is confined in at least one opening of the openings of the growth mask and does not extend outside of said at least one opening.

It is understood that the features and advantages of an aspect of the invention can be transposed, mutatis mutandis, to another aspect of the invention.

### BRIEF DESCRIPTION OF THE FIGURES

The aims, objectives, as well as the features and advantages of the invention will emerge best from the detailed description of an embodiment of the latter which are illustrated by the following accompanying drawings, wherein:

FIGS. 1A to 1E illustrate a method for forming an optoelectronic device according to an embodiment of the present invention.

FIGS. 2A to 2F illustrate a method for forming an optoelectronic device according to another embodiment of the present invention.

FIG. 3A is a transmission electron microscopy (TEM) image of an optoelectronic device according to an embodiment of the present invention.

FIG. 3B is a scanning transmission electron microscopy (STEM) image of an optoelectronic device according to an embodiment of the present invention.

FIGS. 4A to 4G illustrate a method for forming an optoelectronic device also according to another embodiment of the present invention.

The drawings are given as examples and are not limiting of the invention. They constitute principle schematic representations intended to facilitate the understanding of the invention and are not necessarily to the scale of practical applications. In particular, the dimensions of the different elements of the optoelectronic device are not representative of reality.

### DETAILED DESCRIPTION

Before starting a detailed review of embodiments of the invention, it is reminded that the invention, according to its first aspect, in particular comprises the optional features below which could be used in association or alternatively.

According to an example, the injection layer of the first type of carriers is confined in the at least one opening of the growth mask.

According to an example, the injection layer of the first type of carriers bears on a nucleation layer made of a material different from the material of said injection layer.

According to an example, said at least one stack is laterally bordered by a wall of the at least one opening, over a height greater than or equal to the sum of the thicknesses of the injection layer and of the active layer.

According to an example, the stack further comprises distributed Bragg reflectors (DBR) so as to form a resonating cavity in the longitudinal direction.

According to an example, the device comprises a first stack and a second stack respectively comprising a first active layer and a second active layer respectively confined in a first opening and a second opening of the growth mask, said first and second openings respectively having a first surface and a second surface, taken in a plane transverse to the longitudinal direction, different from one another, and said first and second active layers respectively have a first thickness and a second thickness, taken in the longitudinal direction, different from one another.

According to an example, the first and second stacks respectively comprise a first injection layer of the first type of carriers and a second injection layer of the first type of carriers respectively confined in the first and second openings of the growth mask, said first and second injection layers respectively have a first thickness and a second thickness, taken in the longitudinal direction, different from one another.

According to an example, the device comprises a plurality of stacks and of active layers confined in a plurality of openings of the growth mask, and the openings having surfaces, taken in a plane transverse to the longitudinal direction, substantially equal to one another are separated two-by-two by a separation distance ds chosen such that said openings form a resonating cavity in a plane transverse to the longitudinal direction. Said resonating cavity is therefore typically formed by a plurality of stacks of the same size, more specifically with a size less than 1 pm. This makes it possible to form a photonic crystal. This consequently enables a more precise and reliable selection of the emission wavelength, due to the filter formed by the photonic crystal.

A resonating cavity is, in this case, intrinsically linked to the existence of an array of openings of the same size or of the same surfaces. Thus, three openings have three different sizes, for example to emit at three different lengths, do not suffice to form a resonating cavity. It is in particular necessary to have a plurality of openings of the same size, ordered according to a regular array, to form a resonating cavity in the plane transverse to the longitudinal direction.

The formation of a photonic crystal involves, in particular a very low tolerance on the step of the opening array and on the diameter of the stacks. Thus, a growth of the stacks through a growth stack – rather than on a flat substrate – advantageously enables an excellent control of the critical dimensions enabling the obtaining of this photonic crystal (separation distance, opening size).

The solution retained in the scope of the present invention further makes it possible to be released from the constraint of a very homogenous and dense filling between the stacks, which is difficult to obtain for separation distances less than 1 µm such as required to produce a photonic crystal.

According to an example, a planarisation is produced after the growth of the stacks, for example using a filling of the openings above the stacks by a planarisation material. This planarisation can be achieved by deposition by centrifugation (known as “spin coating”), optionally followed by a chemical mechanical polishing (CMP). This planarisation improves the quality of the photonic crystal.

According to an example, the injection layer of the first type of carriers has a front face in contact with the active layer within the opening, and a rear face opposite the front face and in contact with a transparent conducting layer. This makes it possible to form a device having a transparent contact on the rear face. Such a device can advantageously be produced by a flip chip method.

The invention, according to its second aspect comprises, in particular the optional features below which could be used in association or alternatively:

According to an example, the formations of the injection layer and of the active layer are produced by metalorganic vapour-phase epitaxy (MOVPE) in the longitudinal direction in the at least one opening.

According to an example, the growth mask comprises at least one first opening and one second opening respectively having a first surface and a second surface, taken in a plane transverse to the longitudinal direction, different from one another.

According to an example, the formation of the active layer comprises a formation of a first active layer within the first opening and simultaneously, a formation of a second active layer within the second opening, such that said first and second active layers have thicknesses, taken in the longitudinal direction, different from one another.

According to an example, the growth mask comprises a plurality of openings.

According to an example, the openings having surfaces, taken in a plane transverse to the longitudinal direction, substantially equal to one another are separated two-by-two by a separation distance ds chosen such that said openings form a resonating cavity in a plane transverse to the longitudinal direction. According to an example, several resonating cavities can be formed by way of one single growth mask. Thus, a plurality of first openings having a first size and separated by a first separation distance corresponding to a first array step, typically form a first resonating cavity. A plurality of second openings having a second size and separated by a second separation distance corresponding to a second array step, typically form a second resonating cavity. A plurality of third openings having a third size and separated by a third separation distance corresponding to a third array step, typically form a third resonating cavity. These first, second and third resonating cavities can coexist within the growth mask, for example respectively at first, second and third juxtaposed and distinct zones of the growth mask, or in an interweaved manner. These first, second and third resonating cavities typically make it possible to filter and/or exacerbate the emission of light according to first, second and third wavelengths.

According to an example, the separation distance ds is between 50 nm and 700 nm.

According to an example, the substrate comprises a layer made of a semiconductor material on the nucleation layer and the formation of the growth mask comprises:
An etching of the layer made of a semiconductor material, from an upper face until an interface with the nucleation layer, so as to form the at least one opening exposing the zone of the nucleation layer,
A passivation at least at the upper face of the layer made of a semiconductor material and a wall of the at least one opening.

The production of the growth mask made of a passivated semiconductor material makes it possible to better control the diameter and the positioning of the openings for openings of a significant height. This makes it possible, in particular, to limit or to avoid the appearance of deformations along the height of the openings.

The passivation of the openings makes it possible to use GaN to produce a large part of the growth mask. This makes it possible to avoid resorting to the deposition of a specific material to form the growth mask. The GaN-based substrate can be directly used as a growth mask model. Thus, the etching of the openings is performed directly in said substrate, and a simple passivation step can typically suffice to finalise the formation of the growth mask. The mask is thus produced in a layer made of a semiconductor or conducting material, such as GaN, passivated at the walls of the openings and between the openings. The bottom of the openings is not passivated, or the passivation layer is removed at the bottom of the openings, so as to enable the growth of the stacks in the openings. The openings are preferably produced only over some of the height of the GaN-based layer of the substrate, such that the bottom of the openings corresponds directly to an exposed part of said GaN-based layer.

Such a growth mask comprising a part of the GaN-based substrate advantageously makes it possible to significantly increase the quality of the growth of the stacks in the openings. The part of the GaN-based substrate forming the bottom of the openings forms a nucleation layer for the growth of the stack. It is therefore not necessary to provide an additional nucleation layer on the bottom of the openings. This makes it possible to reduce the total thickness of the stack. This reduction in thickness of the stack considerably improves the crystalline quality of the different layers of the stack, in particular of the active zone buried within the stack.

Moreover, the passivation of the sides or walls of the openings, which enables a growth directed in the longitudinal direction, without interfering growth on the sides of the openings, also makes it possible to avoid the recombinations of carriers which can occur on the perimeter of the stacks.

This passivation also makes it possible to inhibit the growth of the stack layers on the upper face or the top of the growth mask. This makes it possible to favour the growth of the stacks at the bottom of the cavities. This passivation also makes it possible to insulate the upper layers of the stacks, for example the GaN-p-based hole injection layer, against the substrate, for example GaN-n-based.

Moreover, the semiconductor-based part such as a growth mask can advantageously improve the extraction of light and/or modulate the far field of the light emission. The choice in the composition of the semiconductor can, in particular, exacerbate one and/or the other of these effects.

According to an example, the method comprises, before passivation, a formation of a reflective layer at least partially on the wall of the at least one opening.

According to an example, the method comprises, after formation of the active layer:
A formation of an electron blocking layer on the active layer,
A formation of an injection layer of a second type of carriers (pGaN) on the electron blocking layer,
A formation of metal contacts on said injection layer of the second type of carriers (pGaN),
A provision of a second substrate,
An assembly of said second substrate at the metal contacts,
A removal of the substrate (1) comprising the at least one nucleation layer (11),
A formation of transparent electrical contacts at the injection layer of the first type of carriers (30). Such a method is “flip chip” type.

According to an example, the growth mask comprises a plurality of openings distributed along the first, second and third subassemblies respectively comprising openings having first, second and third middle surfaces, taken in a plane transverse to the longitudinal direction, different from one another.

According to an example, the first, second and third middle surfaces are chosen so as to respectively form first, second and third subassemblies respectively comprising active layers having first, second and third thicknesses, taken in the longitudinal direction, different from one another, said subassemblies of active layers being configured to emit light radiations respectively having first, second and third wavelengths, different from one another.

According to an example, the first, second and third wavelengths belong to the visible electromagnetic spectrum and are chosen in this spectrum so as to respectively emit a red, green and blue light.

According to an example, the formation of the injection layer of the first type of carries is performed simultaneously within all the openings such that the thickness of said injection layer varies according to the surface, taken in a plane transverse to the longitudinal direction, of the openings.

According to an example, the formation of the active layer is performed simultaneously within all the openings, such that the thickness of said active layer varies according to the surface, taken in a plane transverse to the longitudinal direction, of the openings.

According to an example, the injection layer of the first type of carriers (30) is GaN-based, and the active layer is InGaN-based.

Except for incompatibility, it is understood that the manufacturing method and the optoelectronic device can comprise, mutatis mutandis, any one of the optional features above. Except specific indication on the contrary, technical features described in detail for a given embodiment can be combined with the technical features described in the context of other embodiments described as an example and in a non-limiting manner. In particular, the number of openings, the different shapes of openings and/or the different separation distances illustrated in the figures can be combined so as to form another embodiment which is not necessarily illustrated or described. Such an embodiment is clearly not excluded from the invention.

In the present invention, the manufacturing method is, in particular, dedicated to the manufacture of LEDs having a 3D architecture (3D LED).

The invention can be implemented more broadly for different optoelectronic devices with a 3D architecture, and in particular those comprising active layers.

By active layer or active region of an optoelectronic device, this means the layer or the region from which the majority of the light radiation supplied by this device is emitted, or the region from which the majority of the light radiation received by this device is captured.

The invention can therefore also be implemented in the scope of laser or photovoltaic devices.

Unless explicitly mentioned, it is specified that, in the scope of the present invention, the relative arrangement of a third layer interleaved between a first layer and a second layer, does not compulsorily mean that the layers are directly in contact with one another, but means that the third layer is either directly in contact with the first and second layers, or separated from these by at least one other layer or at least one other element. For example, an electron blocking layer interleaved between the active layer and the injection layer of the second type of carriers is not necessarily directly in contact with one or the other, and other layers having other functions can be optionally added.

The steps of forming different elements (growth mask, injection layers and active layer, etc.) are meant in the broad sense: they can be carried out in several substeps which are not necessarily strictly successive.

By diameter, this means the largest transverse dimension of the opening. In the present invention, the openings do not necessarily have a circular transverse cross-section. In particular, in the case of openings formed from a GaN-based layer, this cross-section can be hexagonal. The diameter thus corresponds to the distance separating two opposite tops of the hexagonal cross-section. Alternatively, the diameter can correspond to a middle diameter calculated from the diameter of a circle inscribed in the polygon of the transverse cross-section and of the diameter of a circumscribed circle of this polygon.

The separation distance ds is the smallest distance separating two adjacent openings.

In the present patent application, the terms “light-emitting diode”, “LED” or simply “diode” are used as synonyms. An “LED” can also mean a “micro-LED”.

Below, the following abbreviations relating to a material M are optionally used:
M-i refers to the intentionally doped intrinsic or not material M, according to the terminology usually used in the microelectronics field for the suffix -i.
M-n refers to the N-doped, N+-doped or N++-doped material M, according to the terminology usually used in the microelectronics field for the suffix -n.
M-p refers to the P-doped, P+-doped or P++-doped material M, according to the terminology usually used in the microelectronics field for the suffix -p.

By a substrate, a layer, a device, “with the basis” of a material M, this means a substrate, a layer, a device comprising this material M only or this material M and optionally other materials, for example alloy elements, impurities or doping elements. Thus, a gallium nitride (GaN)-based layer can, for example, comprise gallium nitride (GaN or GaN-i) or doped gallium nitride (GaN-p, GaN-n). A gallium-indium nitride (InGaN)-based active region can, for example, comprise gallium-aluminium nitride (AlGaN) or gallium nitride with different aluminium and indium (GalnAIN) contents.

A marker, preferably orthonormal, comprising the axes x, y, z is represented in the accompanying figures.

In the present patent application, preferably thickness will be referred to for a layer and height for a structure or a device. The thickness is taken along a direction normal to the main extension plane of the layer, and the height is taken perpendicularly to the basal plane xy of the substrate. Thus, an active layer typically has a thickness along z, and an LED has a height along z. A thickness of an axial deposition is taken along z. The longitudinal direction is parallel to z. The terms “vertical” and “lateral” mean directions taken respectively along z and perpendicularly to z.

The dimensional values mean manufacturing and margin tolerances. Thus, two identical separation distances ds or two identical opening diameters in theory, can have a slight dimensional variation in practice.

The terms “substantially”, “about”, “around” mean, when they relate to a value, “roughly 10%” of this value or, when they relate to an angular orientation, “roughly 10°” of this orientation. Thus, a direction substantially normal to a plane means a direction having an angle of 90±10° with respect to the plane.

To determine the geometry of the devices and the compositions of different elements (active layer, growth mask, for example) of these devices, Scanning Electron Microscopy (SEM) or Transmission Electron Microscopy (TEM) or also Scanning Transmission Electron Microscopy (STEM) analyses can be proceeded with.

TEM or STEM in particular lend themselves to the observation and to the identification of quantum wells – the thickness of which is generally around a few nanometres – in the active layer. Different techniques listed below non-exhaustively can be implemented: dark field and bright field, weak beam, high angle annular dark field (HAADF) imaging.

The chemical compositions of different elements can be determined using the well-known EDX or X-EDS (energy dispersive X-ray spectroscopy) method.

This method is well adapted for analysing the composition of optoelectronic devices of small sizes, such as 3D LEDs. It can be implemented on metallurgic cross-sections within a Scanning Electron Microscope (SEM) or on thin slides within a Transmission Electron Microscope (TEM).

The optical properties of the different elements, and in particular the main wavelengths for emitting GaN-based axial 3D LEDs and/or InGaN-based active layers, can be determined by spectroscopy.

Cathodoluminescence (CL) and photoluminescence (PL) spectroscopies are well adapted to optically characterise the 3D structures described in the present invention.

The techniques mentioned above can in particular make it possible to determine if an axial 3D architecture optoelectronic device comprises an active layer and/or InGaN-based quantum wells directly formed within a growth mask. Such a growth mask can be an indicator of an implementation of an MOVPE-type deposition, such as described in the present invention.

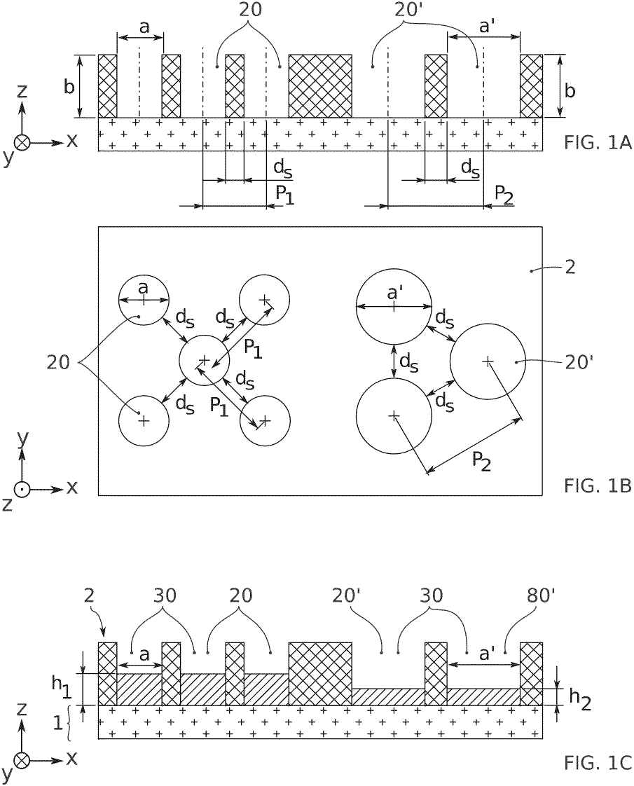

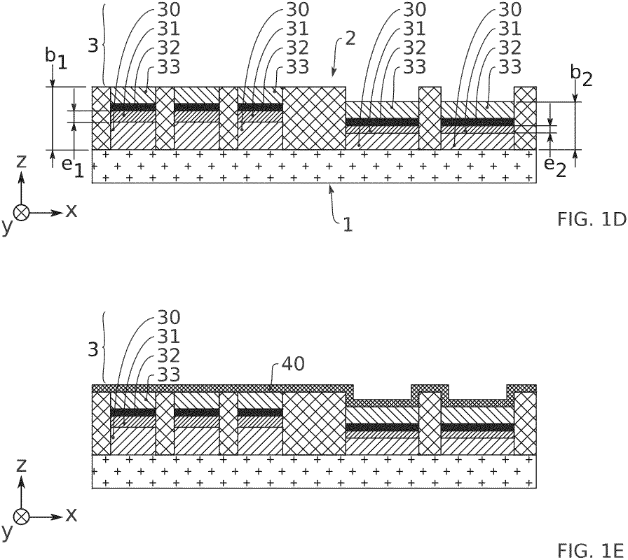

A first example of an embodiment of an axial 3D architecture optoelectronic device according to the invention will now be described in reference to FIGS. 1A to 1E. The present invention also relates to a method for manufacturing an optoelectronic device such as described through the examples of embodiments below.

FIG. 1A illustrates in a transverse cross-section, the formation of a growth mask 2 on a substrate 1. This growth mask 2 can be formed of a dielectric material, for example made of silicon oxide. It typically comprises a plurality of openings 20, 20′ leading to the substrate 1. Such a growth mask 2 is configured to guide the growth of the active layer and/or injection layers of carriers (electrons and/or holes) within each opening 20, 20′.

The substrate 1 can in particular be presented in the form of a bulk support made of sapphire or silicon. In the latter case, it can be presented in the form of a wafer of diameter 200 mm or 300 mm. This makes it possible to reduce the costs. This also makes it possible to improve the technological compatibility with microelectronic technologies. The sapphire can be presented in the form of a wafer of diameter 200 mm and makes it possible to limit the mesh parameter difference with GaN. The substrate 1 in particular serves as a support for the optoelectronic device. It can act as a mechanical support and/or epitaxy support. The substrate 1 can advantageously be limited to the sole bulk support, without any additional superficial layer. It can be substantially flat and parallel to the plane xy. Alternatively, it can be textured and/or comprise patterns. According to an example, the substrate 1 is a sapphire substrate with patterns also called PSS (patterned sapphire substrate) known to a person skilled in the art. These patterns can have varied shapes, for example a conic shape, hemispherical, pyramidal.

Alternatively, the substrate 1 can be presented in the form of a stack comprising, in the direction z, the support and at least one other layer, for example a buffer layer. This buffer layer can be GaN- or polySi-based. According to another possibility, it can be with the basis of other metal nitrides, for example AIN. It can be formed on the silicon or sapphire support by epitaxy, preferably by metalorganic vapour-phase epitaxy (MOVPE). It can have a thickness of around a few hundred nanometres, for example 10 nm to 10 microns.

The substrate 1 can also comprise, alternatively or combined with the buffer layer, a nucleation layer, typically GaN-based. Such a nucleation layer typically has a low thickness, for example less than 100 nm. This makes it possible to improve the crystalline quality of this GaN-based nucleation layer.

The growth mask 2 is formed preferably directly on the substrate 1. It can have a height b of around a few tens of nanometres, for example about 50 nm, to a few microns, for example around 2 µm. It preferably comprises a plurality of openings 20, 20′. Such a growth mask 2 is typically formed by a deposition step, for example a chemical vapour deposition (CVD), followed by a lithography/etching step configured to define the openings (FIG. 1A). The growth mask can be made of a dielectric material, for example silicon oxide or silicon nitride, or in a combination of dielectric materials.

The openings 20, 20′ lead to a surface of the substrate 1. They preferably have one or more walls substantially perpendicular to the plane xy of the substrate 1. The openings 20, 20′ have a closed contour in the plane xy. They typically have a lateral dimension taken in the plane xy, for example a diameter or a middle diameter, between 50 nm and 500 nm. These openings 20, 20′ are preferably circular. As illustrated in FIG. 1A, they can advantageously have different diameters a, a′.

The openings 20, 20′ are separate from one another by a separation distance ds, for example between 50 nm and 700 nm. The openings 20, 20′ can be distributed regularly within the growth mask 2, for example in the form of one or more ordered arrays. In the example illustrated in FIG. 1B as a top view, the openings 20, 20′ are distributed along two arrays, each having a different step. The step p1, p2 of each array, i.e. the distance separating the centres of two adjacent openings of one same array, is preferably less than or equal to 1 µm. The step of an array of openings having a given diameter is equal to the sum of the diameter and of the separation distance ds separating two adjacent openings of this array. It can be between 100 nm and 1 µm. The step p1, p2 of each array of openings 20, 20′ is chosen so as to form a resonating cavity in a direction parallel to the plane xy, for a determined emission wavelength. A growth mask 2 comprising ordered openings along one or more arrays therefore makes it possible to form one or more photonic crystals.

The openings 20, 20′ are configured to each receive a stack 3 comprising at least one injection layer 30 of carriers of a first type, for example electrons, and an active layer 31.

The electron injection layer 30 of the stack 3 is preferably GaN-based, in particular GaN-n-based. It is preferably oriented parallel to z in a crystallographic direction [0001] corresponding to the axis c of a hexagonal crystallographic structure.

The formation of this GaN-n-based electron injection layer 30 can be achieved by epitaxy, preferably by metalorganic vapour-phase epitaxy (MOVPE). It is preferably achieved simultaneously in each opening 20, 20′ of the growth mask 2.

As illustrated in FIG. 1C, the electron injection layer 30 is formed on the exposed surface of the substrate 1, at the bottom of each opening 20, 20′. In each opening, the growth of the layer 30 is laterally constrained by the wall of the opening 20, 20′. The layer 30 thus progressively fills the opening in question. The volume of each layer 30 deposited or epitaxially grown simultaneously within each opening 20, 20′ is substantially constant. The thickness h1, h2 of the layer 30 thus advantageously depends on the lateral dimension a, a′ of the opening 20, 20′ in question. In the example illustrated in FIG. 1C, the layer 30 advantageously has a thickness h1 for each opening 20 of diameter a, and a thickness h2 for each opening 20′ of diameter a′. The larger the opening diameter is, and the thinner the layer 30 thickness is.

The active layer 31 of the stack 3 is preferably InGaN-based. It preferably comprises a plurality of InGaN-based quantum wells. These quantum wells are typically configured to emit a light radiation according to a main wavelength A. They can be conventionally separated from one another by GaN-based barriers.

According to a preferred possibility, the InGaN-based quantum wells of the active layer 31 extend parallel to the plane xy of the substrate 1, along crystallographic planes of type c {0001}. The stack 3 comprising such an active layer 31 advantageously has an axial architecture. This axial architecture in particular makes it possible to incorporate a significant concentration of indium [In] in the quantum wells of the active layer 31. The more the concentration of indium [In] of the InGaN-based quantum wells increases, the more the main wavelength increases.

The formation of this active layer 31 can be performed by period deposition of InGaN quantum wells and GaN barriers by MOVPE. It is preferably performed simultaneously in each opening 20, 20′ of the growth mask 2 (FIG. 1D).

As illustrated in FIG. 1D, the active layer 31 can be formed directly on the injection layer 30 of carriers, in each opening 20, 20′. In each opening, the growth of the active layer 31 is laterally constrained by the wall of the opening 20, 20′. The active layer 31 thus progressively fills the opening in question. The volume of each active layer 31 deposited or epitaxially grown simultaneously within each opening 20, 20′ is substantially constant. The thickness e1, e2 of the active layer 31 thus advantageously depends on the lateral dimension a, a′ of the opening 20, 20′ in question. The incorporation of indium also advantageously depends on the lateral dimension a, a′ of the opening 20, 20′ in question. In the example illustrated in FIG. 1D, the active layer 31 advantageously has a thickness e1 for each opening 20 of diameter a, and a thickness e2 for each opening 20′ of diameter a′. The larger and opening diameter is, the thinner the thickness of the active layer 31 is. The larger the opening diameter is, the lower the concentration of indium [In] in the wells of the active layer 31 is. This means that the main wavelength emitted by the stacks 3 formed within the largest openings, is smaller than the main wavelength emitted by the stacks 3 formed within the smallest openings. In FIG. 1D, the openings 20 of diameter a can be configured such that the stacks 3 formed in said openings 20 have a main emission wavelength of around 525 nm, in the green, and the openings 20′ of diameter a′ can be configured such that the stacks 3 formed in said openings 20′ have a main emission wavelength of around 450 nm, in the blue.

The method thus advantageously makes it possible to simultaneously form several stacks 3 emitting several main wavelengths, in particular according to the size features of the openings of the growth mask 2.

The stacks 3 typically comprise, in addition to the electron injection layer 30 and the active layer 31, a hole injection layer 33, for example GaN-p-based. They can also comprise an electron blocking layer 32 interleaved between the active layer 31 and the hole injection layer 33, in a known manner (FIG. 1D). These layers 32, 33 can be fully confined in the openings 20, 20′, such as illustrated in FIG. 1D. According to a possibility, the hole injection layer 33 can extend at least partially outside of the corresponding opening. The stack 3 of the layers 30, 31, 32, 33 typically forms an axial 3D LED. The stack 3 can optionally comprise other non-illustrated layers, for example layers forming distributed Bragg reflectors. In the example illustrated in FIG. 1D, the stack 3 advantageously has a thickness b1 for each opening 20 of diameter a, and a thickness b2 for each opening 20′ of diameter a′.

An electrical contact can then be formed on the hole injection layers 33. Such a contact can be presented in the form of a conducting layer 40, for example made of metal or of transparent conducting oxide (TCO), such as illustrated in FIG. 1E.

The device thus formed advantageously comprises axial 3D LEDs passivated by the growth mask 2. The growth mask 2 further makes it possible to laterally encapsulate the stacks 3. The mechanical strength of the device is thus ensured. The stacks are advantageously distributed, according to the size of the openings wherein they are formed, in subassemblies emitting at different main wavelengths. This makes it possible, in particular, to form subpixels of different colours, typically red, green and blue (RGB). These subpixels can be organised according to photonic arrays, such as illustrated in FIG. 1B, to improve the light emission intensity. According to another possibility, they can be disposed alternately from one another, typically to form a pixel from three RGB subpixels.

The method for manufacturing this device advantageously makes it possible to obtain stacks of different sizes, emitting at different wavelengths, during one single growth sequence of each of the layers of stacks. It further makes it possible to implement 2D-type growth conditions to produce 3D stacks. This enables the formation of active layers comprising quantum wells along c-type crystallographic planes {0001}, in a 3D stack epitaxially grown by MOVPE. The method thus makes it possible to manufacture an optoelectronic device, in particular LED-based, combining the advantages of the 2D growth conditions and the advantages of 3D stack architectures.

The choice of the diameter of the openings and of the separation distance between the openings further makes it possible to control the thickness of the active layers and the incorporation of indium within active layers of these openings, so as to ultimately adjust the main emission wavelength of the stacks.

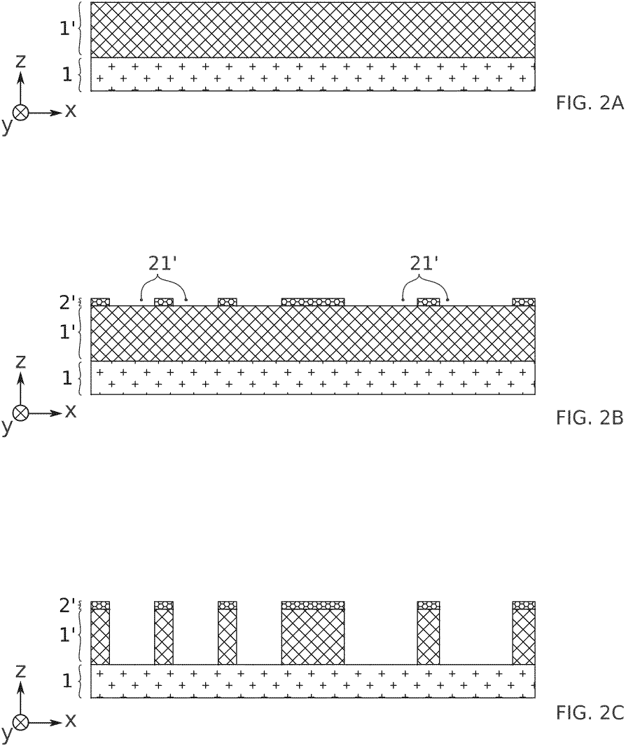

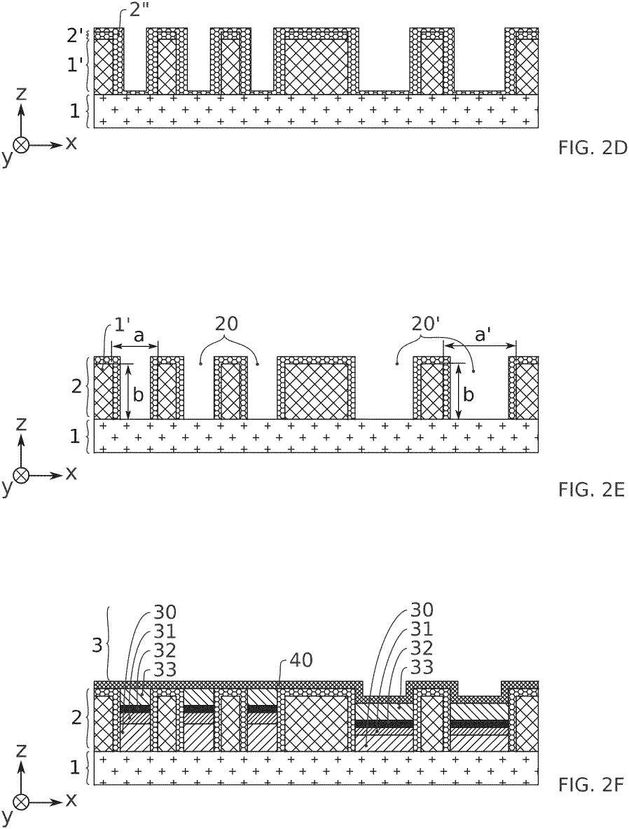

A second example of an embodiment is illustrated in FIGS. 2A to 2F. This second example has an alternative of an embodiment of the growth mask 2. According to this second example, the substrate 1 is surmounted by a layer 1′, for example made of GaN (FIG. 2A). This GaN layer 1′ is then structured and passivated so as to form the growth mask 2.

A hard mask 2′ is formed beforehand by lithography on the surface of the GaN layer 1′ (FIG. 2B). This hard mask 2′ can be conventionally made of silicon oxide (SiO₂) or of silicon nitride (SiN). It comprises openings 21, 21′ of the same shape as the openings 20, 20′ to be made in the growth mask 2. These openings 21, 21′ have lateral dimensions slightly greater than the dimensions of the openings 20, 20′ to be made in the growth mask 2.

An anisotropic etching of the layer 1′, along z and over the whole thickness of the layer 1′, is then performed (FIG. 2C). This etching can be performed in a known manner by plasma in chlorinated chemistry, for example from a Cl₂/Ar or SiCl₄/Ar mixture.

A passivation of the exposed walls of the layer 1′ is then performed, typically by deposition of an SiO₂ or SiN dielectric layer 2″ (FIG. 2D). This layer 2″ is continuous and preferably conform. It is preferably with the basis of the same dielectric material as the hard mask 2′.

An etching of the dielectric material is then performed so as to expose the surface of the substrate 1 while preserving a thickness of dielectric material on the surfaces of the GaN layer 1′. The growth mask 2 and the openings 20, 20′ of the growth mask 2 are thus formed. This etching can be isotropic if the deposition of the layer 2″ is conform, or anisotropic along z if the deposition of the layer 2″ is non-conform. These options can be chosen so as to obtain a substantially constant thickness of dielectric material on the surfaces of the GaN layer 1′.

The growth and/or the respective deposition of the electron injection layer 30, the active layer 31, the electron blocking layer 32 and the hole injection layer 33 can then be performed as above within this growth mask 2 (FIG. 2F). Other embodiments of the growth mask 2 can be considered, without this modifying the principle of the invention.

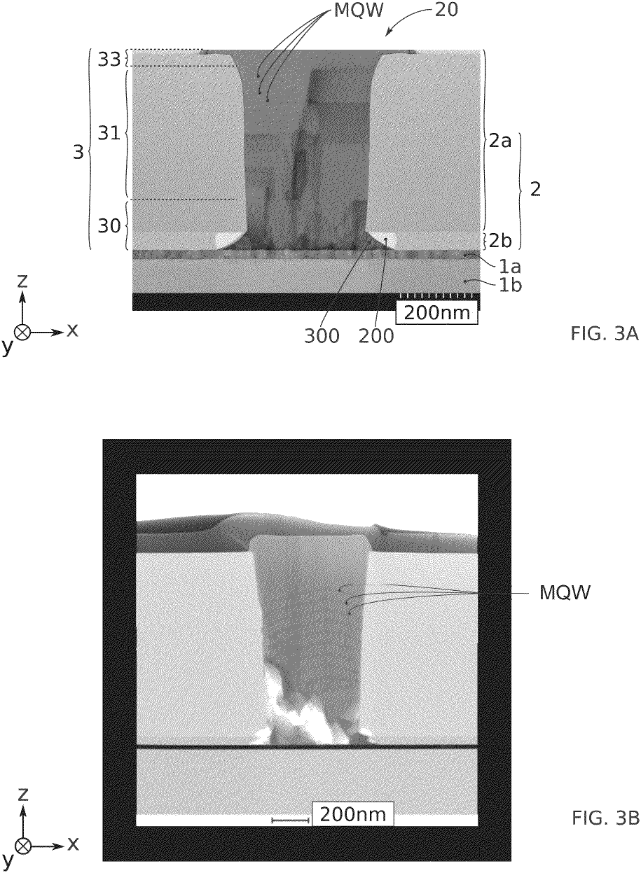

FIG. 3A shows a transmission electron microscopy (TEM) image of a stack 3 formed within an opening of a growth mask 2 according to the principle of the method described in this invention. The growth mask 2 used for this proof of concept illustrated in FIG. 3A comprises, in a variant, a very thick SiN layer 2a and a thin SiO₂ layer 2b. It has a height of around 1 µm. The substrate 1 used for this proof of concept comprises, in a variant, a nucleation layer 1a and a support layer 1b.

The GaN-n electron injection layer 30, the active layer 31 and the GaN-p hole injection layer 33 have been successively epitaxially grown within the opening 20 of the growth mask 2. The MQW quantum wells of the active layer 31 extend substantially parallel to the plane xy of the surface of the substrate 1. This appears even more clearly in FIG. 3B showing a scanning transmission electron microscopy (STEM) image of this type of stack 3. The stack 3 of the different layers 30, 31, 33 therefore forms an axial architecture. The cavity 200 extending to the base of the opening 20 is in this case, due to an overetching during the production of the opening 20 (FIG. 3A). This cavity 200, in this case, houses a growth base 300 of the GaN-n layer 30. The cavity 200 and the growth base 300 illustrated in this proof of concept in FIG. 3A are only optional. They are not necessary, nor damaging to the optoelectronic device.

Advantageously, the growth of the different layers by MOVPE directly within the opening 20 does not induce structural defects in the different layers 30, 31, 33 at the interface with the growth mask 2 (FIG. 3A). The growth mask 2 thus advantageously makes it possible to guide the growth of the stack without generating defects. It further makes it possible to directly passivate the vertical sides, i.e. substantially parallel to z, of the stack 3.

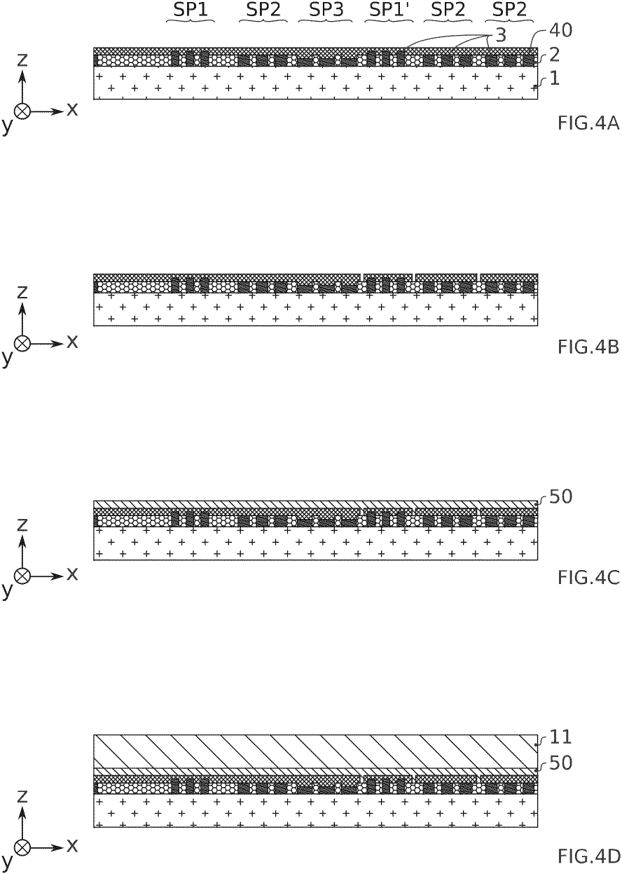

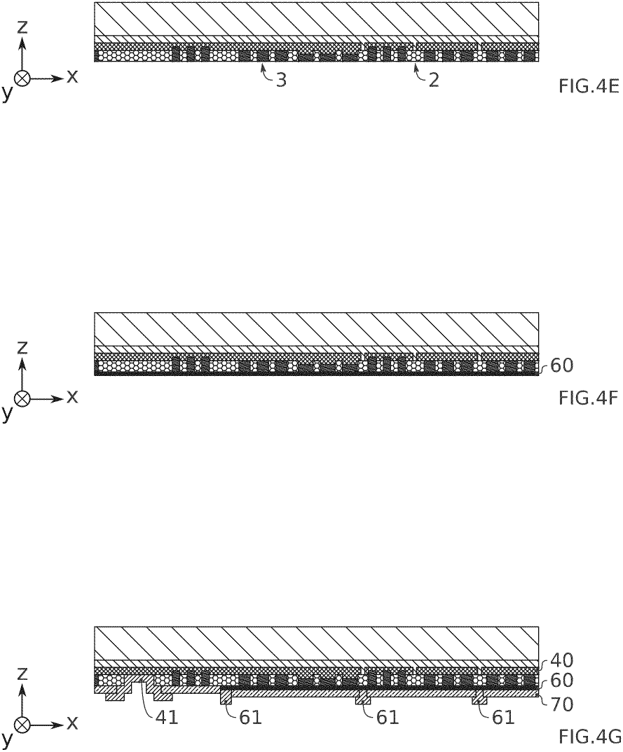

A third example of a “flip chip”-type production method is illustrated in FIGS. 4A to 4G. According to this third example, the device comprises a plurality of stacks 3 distributed within the growth mask 2 in different subassemblies SP1, SP2, SP3, SP1′ (FIG. 4A). These subassemblies SP1, SP2, SP3, SP1′ of stacks 3 are advantageously formed within openings of the growth mask 2 having different diameters, so as to form subpixels emitting at different wavelengths, typically in the red, the green and the blue. The different subassemblies SP1, SP2, SP3, SP1′ are formed as above on a first substrate 1, through openings, then covered by a metal layer 40 (FIG. 4A). This metal layer 40 is typically in contact with the GaN-p layers of the stacks 3. The metal layer 40 is then structured so as to form distinct contacts on different subpixels taken from among the subassemblies SP1, SP2, SP3, SP1′ (FIG. 4B). A silicon oxide layer 50 is then deposited, for example by plasma-enhanced chemical vapour deposition (PECVD), on the front face of the first substrate 1 so as to cover the structures formed beforehand (FIG. 4C). This SiO₂ layer 50 makes it possible to assemble, for example by molecular bonding, a second substrate 11 on the front face of the first substrate 1 comprising the structures of the device (FIG. 4D). The second substrate 11 is typically made of silicon. The first substrate 1 is thus removed, for example by trimming and polishing from its rear face, so as to expose the base of the stacks 3 and of the growth mask 2 (FIG. 4E). A transparent conducting oxide (TCO) layer 60 can then be deposited “on the rear face”, on the base of the stacks 3 and of the growth mask 2 (FIG. 4F). This TCO layer 60 is typically in contact with the GaN-n layers of the stacks 3. A passivation layer 70, for example made of silicon oxy-nitride SiON, can then be deposited on the rear face. The n-type contacts 61 on the TCO layer 60 and the p-type contacts 41 on the metal layer 40 are then respectively structured, for example in the form of vias (FIG. 4G).

Such a method making it possible to return the chip supporting the optoelectronic device is generally known by “flip chip”. It makes it possible to manufacture a device emitting through the rear face. The metal layer 40 can typically act as a reflector in such a device.

The method according to the invention advantageously makes it possible to produce different RGB subpixels based on 3D architectures, according to one single and same growth sequence, with growth conditions close to the two-dimensional growth methods.

The invention is not limited to the embodiments described above and extends to all the embodiments covered by the claims.

1. An optoelectronicdevice comprising a substrate and, on a first face of the substrate, at least one stack in a longitudinal direction, said stack comprising at least one injection layerof a first type of carriers and an active layer, wherein the device being comprises a growth maskcomprising a plurality of openings and wherein the active layeris confined in one of the openings and does not extend outside of said opening.

2. The device according to claim 1, wherein the injection layerof the first type of carriers is confined in the opening of the growth mask.

3. The device according to claim 2, wherein the substratecomprises a nucleation layera face of which forms the first face of the substrate, and wherein the injection layerof the first type of carriers bears on the nucleation layer, said nucleation layer being made of a material different from the material of the injection layer.

4. The device according to claim 1, wherein said at least one stackis laterally bordered by a wall of the at least one opening, over a height greater than or equal to the sum of the thicknesses of the injection layerand of the active layer.

5. The device according to claim 1 wherein the at least one stackfurther comprises distributed Bragg reflectors so as to form a resonating cavity in the longitudinal direction.

6. The device according to claim 1 wherein the at least one stackcomprises a first stack and a second stack respectively comprising a first active layer and a second active layer confined respectively in a first openingand a second openingof the growth mask, said first and second openings respectively having a first surface and a second surface, taken in a plane transverse to the longitudinal direction, different from one another, and said first and second active layersrespectively having a first thicknessand a second thickness (e2), taken in the longitudinal direction, different from one another.

7. The device according to claim 6, wherein the first and second stacks respectively comprise a first injection layerof the first type of carriers and a second injection layerof the first type of carriers confined respectively in the first and second openings of the growth mask, said first and second injection layers respectively having a first thicknessand a second thicknesstaken in the longitudinal direction, different from one another.

8. The device according to claim 1, comprising a plurality of stacks each comprising an active layer, and the active layers being confined in a plurality of openings of the growth mask, wherein the openings, having surfaces substantially equal to one another, taken in a plane transverse to the longitudinal direction, are separated two-by-two by a separation distance ds chosen such that said openings form a resonating cavity in a plane transverse to the longitudinal direction.

9. The device according to claim 1 wherein the injection layer of the first type of carriers has a front face in contact with the active layer within the opening, and a rear face opposite the front face and in contact with a transparent conducting layer.

10. A method for manufacturing an optoelectronic device comprising a substrateand, on a first face of the substrate, at least one stack, in a longitudinal direction, of at least one injection layerof a first type of carriers and an active layer, said method comprising:
A provision of the substrate,
A formation of a growth maskon the first face of the substrate, said growth maskcomprising at least one opening in the longitudinal directionthrough which the first face is exposed,
A formation, from the exposed zone of the substrate, of the injection layer of the first type of carriers within the at least one opening
A formation of the active layeron said injection layer, within the at least one opening such that said active layer is confined in the at least one opening and does not extend outside of said at least one opening.

11. The method according to claim 10, wherein the substrate comprises a nucleation layer, a face of which forms the first face of the substrate, such that the injection layer of the first type of carriers is formed within the at least one opening by bearing on said nucleation layer, said nucleation layer being made of a material different from the material of the injection layer of the first type of carriers.

12. The method according to claim 10 wherein the formations of the injection layerand of the active layer are achieved by metalorganic vapour-phase epitaxy (MOVPE) in the longitudinal directionin the at least one opening.

13. The method according to claim 10 wherein the growth mask comprises at least one first opening and one second opening respectively having a first surface and a second surface, taken in a plane transverse to the longitudinal direction, different from one another, and wherein the formation of the active layer comprises a formation of a first active layer within the first opening and simultaneously, a formation of a second active layer within the second opening such that said first and second active layers have thicknesses, taken in the longitudinal direction, different from one another.

14. The method according to claim 10 to 13, wherein the growth mask comprises a plurality of openings and wherein the openings, having surfaces substantially equal to one another, taken in a plane transverse to the longitudinal direction, are separated two-by-two by a separation distance ds chosen such that said openings form a resonating cavity in a plane transverse to the longitudinal direction z.

15. The method according to claim 14, wherein the separation distance ds is between 50 nm and 700 nm.

16. The method Method according to claim 10 wherein the formation of the growth maskcomprises:
A deposition of a layermade of a semiconductor material on the first face of the substrate,
An etching of the layermade of a semiconductor material, from an upper face of said layermade of a semiconductor material until the first face of the substrate, so as to form the at least one opening exposing the first face of the substrate,
A passivation at least at the upper face of the layermade of a semiconductor material and at a wall of the at least one opening.

17. The method according to claim 16 comprising, before passivation, a formation of a reflective layer at least partially on the wall of the at least one opening.

18. The method according to claim 10 comprising, after formation of the active layer:
A formation of an electron blocking layeron the active layer,
A formation of an injection layer of a second type of carriers on the electron blocking layer,
A formation of metal contactson said injection layerof the second type of carriers,
A provision of a second substrate,
An assembly of said second substrateat the metal contacts,
A removal of the substrate,
A formation of transparent electrical contactsat the injection layer of the first type of carriers.

19. The method according to claim 10 wherein the growth maskcomprises a plurality of openings distributed according to the first, second and third subassemblies respectively comprising openings having first, second and third middle surfaces, taken in a plane transverse to the longitudinal direction, different from one another.

20. The method according to claim 19, wherein the first, second and third middle surfaces are chosen so as to respectively form first, second and third subassemblies respectively comprising active layershaving first, second and third thicknesses, taken in the longitudinal direction, different from one another, said subassemblies of active layersbeing configured to emit light radiations respectively having first, second and third wavelengths, different from one another.

21. The method .according to claim 10 to 20, wherein the growth mask comprises a plurality of openings and wherein the formation of the injection layerof the first type of carriers is performed simultaneously within all the openings such that the thickness of said injection layer varies according to the surface, taken in a plane transverse to the longitudinal direction, of the openings, and wherein the formation of the active layer is performed simultaneously within all the openings such that the thickness of said active layer varies according to the surface, taken in a plane transverse to the longitudinal direction, of the openings.

22. The method according to claim 10 wherein the injection layerof the first type of carriers is GaN-based, and the active layeris InGaN-based.
